(19) United States
(12) Patent Application Publication
(10) Pub. No.: US 2006/0151790 A1
(43) Pub. Date: Jul. 13, 2006

(54) Thin film transistor

(75) Inventors: Tae Wook Kang, Seongnam (KR); Chang Yong Jeong, Suwon (KR); Won Kyu Kwak, Seongnam (KR)

Correspondence Address: H.C. PARK & ASSOCIATES, PLC, 8500 LEESBURG PIKE, SUITE 7500, VIENNA, VA, 22182, US

(73) Assignee: Samsung SDI Co., Ltd.

(21) Appl. No.: 11/327,384

(22) Filed: Jan. 9, 2006

(30) Foreign Application Priority Data
Jan. 7, 2005 (KR) 10-2005-0001851

(51) Int. Cl. H01L 29/04

(52) U.S. Cl. 257/72; 257/347; 257/349; 257/E27.112

(57) ABSTRACT

A thin film transistor includes a semiconductor layer arranged on a substrate, a first insulating layer arranged on the substrate and the semiconductor layer, a gate electrode arranged on the first insulating layer, and a second insulating layer formed on the first insulating layer and the gate electrode. The width of the gate electrode may be less than the width of the semiconductor layer to prevent a short.

### CROSS-REFERENCE TO RELATED APPLICATIONS

This application claims priority to and the benefit of Korean Patent Application No. 10-2005-0001851, filed on Jan. 7, 2005, which is hereby incorporated by reference for all purposes as if fully set forth herein.

### BACKGROUND

1. Field of the Invention

The present invention relates to a thin film transistor, and more particularly, to a thin film transistor that may prevent a short between a semiconductor layer and a gate electrode.

2. Discussion of the Background

Generally, thin film transistors may be used for semiconductor memory, liquid crystal displays (LCD), and the like because they are easy to manufacture and integrate. Thin film transistors are widely used for switching pixels in a flat display, such as an LCD.

Thin film transistors may be amorphous silicon thin film transistors or polycrystalline silicon (polysilicon) thin film transistors depending on whether amorphous silicon or polysilicon is used as a semiconductor layer. Generally, amorphous silicon thin film transistors have fine uniformity and steady characteristics, but are not easily used in high speed driving circuits because of low cataphoresis and because they require a separate driving circuit. Polysilicon thin film transistors have a high cataphoresis, and so are easily used as a switching device in a high density liquid crystal display. Furthermore, polysilicon thin film transistors have low optical leakage current and kick back voltage compared to amorphous silicon thin film transistors, thereby providing high reliability.

A conventional polysilicon thin film transistor will now be described with reference to the drawings.

FIG. 1A is a plan view illustrating a portion of a conventional thin film transistor. FIG. 1B is a schematic side sectional view taken along line 1-1 in FIG. 1A. FIG. 2 is an enlarged sectional view of the region II in FIG. 1A and FIG. 1B. FIG. 3 is a photograph of region 11 in FIG. 1A and FIG. 1B.

As shown in FIG. 1A and FIG. 1B, a thin film transistor 100 may be manufactured by sequentially arranging a buffer layer 120, a polysilicon layer 130, a first insulating layer 140, a gate electrode 150, and a second insulating layer 160 on a substrate 110. However, for illustrative purposes, FIG. 1A depicts only the polysilicon layer 130, the gate electrode 150, and contact holes 130a, 130b, and 161. The contact holes 130a and 130b, and contact hole 161 may be arranged to couple the polysilicon layer 130 and the gate electrode 150, respectively, with other elements. As shown in FIG. 1A, the gate electrode 150 and the polysilicon layer 130 cross each other, and the gate electrode 150 covers at least a part of the polysilicon layer 130, for example, at region II.

As shown in FIG. 1B, the buffer layer 120 may be selectively deposited on the substrate 110. The buffer layer may be SiO₂ or the like. The polysilicon layer 130 may be arranged on the buffer layer 120. The polysilicon layer 130 may be formed by depositing an amorphous silicon layer on the buffer layer 120 and irradiating the deposited amorphous silicon layer with an excimer laser. As shown in FIG. 3, the surface of the polysilicon layer 130 may form steps (step coverage), which may include a planar surface and a protruded surface. The steps may form because of the density difference between a liquid phase and a solid phase in the vicinity of the grain boundary in which the amorphous silicon layer is slowly crystallized.

After forming the polysilicon layer 130, the first insulating layer 140 may be deposited on the buffer layer 120 and the polysilicon layer 130. The first insulating layer 140 may also form steps, which may include a planar surface and a protruded surface because the first insulating layer 140 may be formed on the polysilicon layer 130, and may conform to the steps on the polysilicon layer 130 on which it is formed.

The gate electrode 150 may be arranged on the first insulating layer 140 and may have a step shape surface like the first insulating layer 140. A second insulating layer 160 may be arranged on the gate electrode 150 and the first insulating layer 140. A metal layer 170 may be deposited on the second insulating layer 160 and patterned to form source and drain electrodes. A source or drain electrode may be coupled with the gate electrode 150 through contact hole 161.

The first insulating layer 140 may be thin at the portions that are arranged at the edges (ii) of the polysilicon layer 130 because of the step shapes formed where the first insulating layer 140 overlaps the polysilicon layer 130. As shown in FIG. 3, the first insulating layer 140 on the upper side (ii) of the polysilicon layer 130 is only half as thick as the first insulating layer 140 formed over the rest (i) of the polysilicon layer 130. For example, if the first insulating layer 140 in region (i) is about 800 Å thick, the first insulating layer 140 in region (ii) may be about 400 Å thick.

Consequently, when electric power is applied to the thin film transistor 100 to drive the thin film transistor 100, the relatively thin portions of the first insulating layer 140 at the edges of the polysilicon layer may be shorted, thereby causing a breakdown between the polysilicon layer 130 and the gate electrode 150. This may cause the stability of the thin film transistor 100 to deteriorate which may in turn cause the stability of the device using the thin film transistor to deteriorate. Moreover, the problem may be exacerbated when forming the polysilicon layer 130 because poor quality of the etch profile of the surface of the polysilicon layer 130 will cause larger steps on the first insulating layer 140.

### SUMMARY OF THE INVENTION

The present invention provides a thin film transistor capable of preventing a breakdown between a polysilicon layer and a gate electrode.

Additional features of the invention will be set forth in the description which follows, and in part will be apparent from the description, or may be learned by practice of the invention.

The present invention discloses a thin film transistor including a substrate; a semiconductor layer arranged on the substrate; a first insulating layer arranged on the substrate and the semiconductor layer; a gate electrode arranged on the first insulating layer; and a second insulating layer arranged on the gate electrode and the first insulating layer, wherein the width of the gate electrode is less than the width of the semiconductor layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A is a plan view illustrating a portion of a conventional thin film transistor.

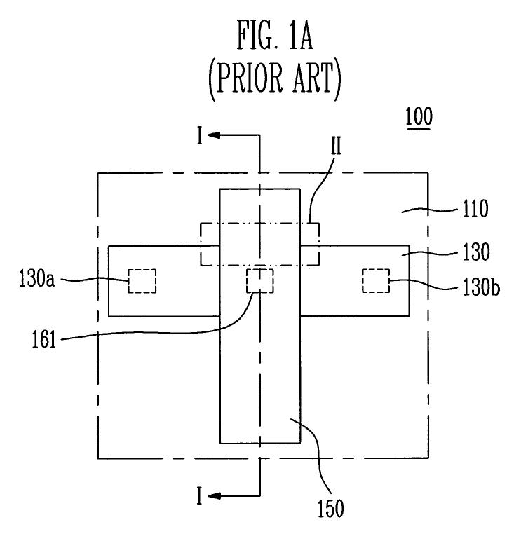

FIG. 1B is a schematic side sectional view taken along line 1-1 in FIG. 1A.

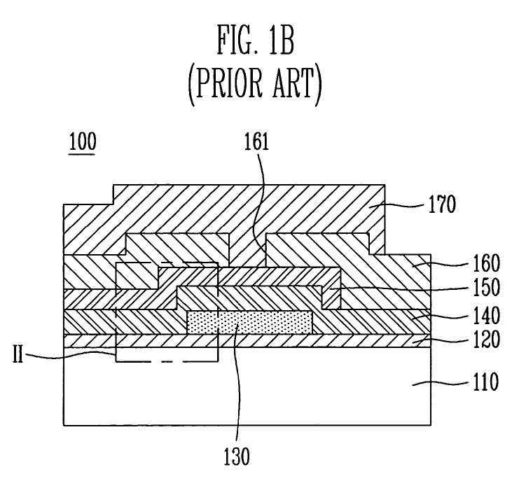

FIG. 2 is an enlarged sectional view of region II in FIG. 1.

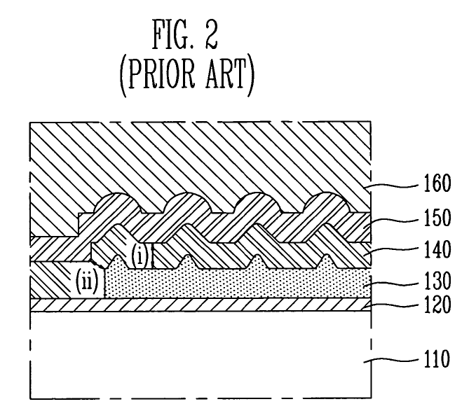

FIG. 3 is a photograph of region II in FIG. 1.

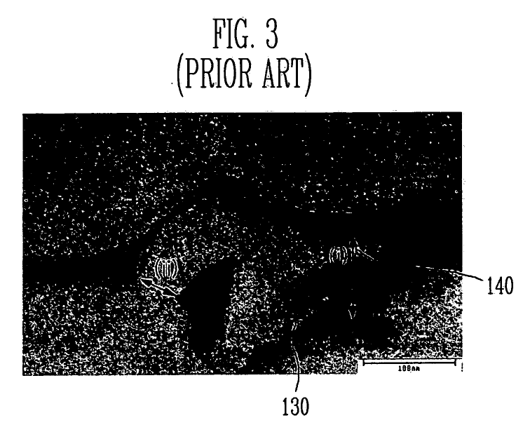

FIG. 4A is a plan view illustrating a portion of a thin film transistor according to an exemplary embodiment of the present invention.

FIG. 4B is a side sectional view taken along line IV-IV in FIG. 4A.

FIG. 5 is an enlarged sectional view of region V in FIG. 4.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity.

It will be understood that when an element such as a layer, film, region or substrate is referred to as being “on” another element, it can be directly on the other element or intervening elements may also be present. In contrast, when an element is referred to as being “directly on” another element, there are no intervening elements present.

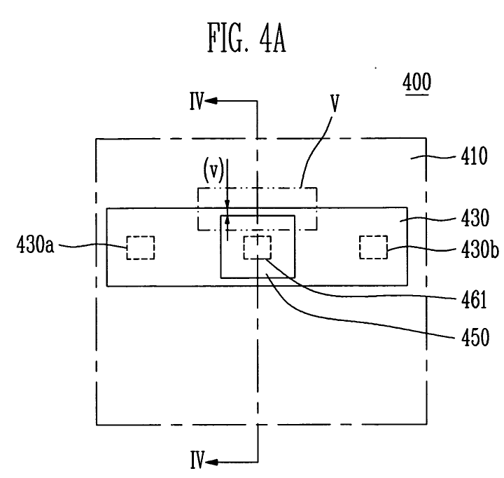

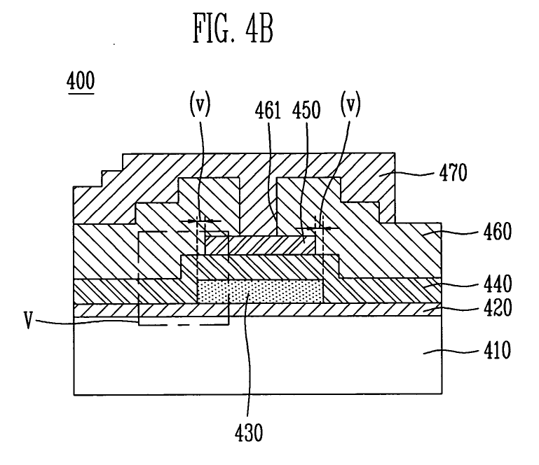

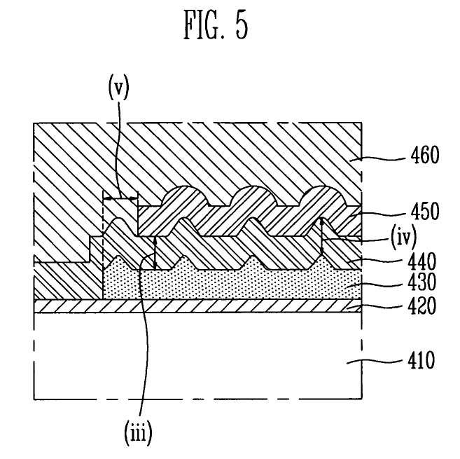

FIG. 4A is a plan view illustrating a portion of a thin film transistor according to an exemplary embodiment of the present invention. FIG. 4B is a side sectional view taken along line IV-IV in FIG. 4A. FIG. 5 is an enlarged sectional view of region V in FIG. 4A and FIG. 4B.

As shown in FIG. 4A, a thin film transistor 400 may include a polysilicon (semiconductor) layer 430, a gate electrode 450, and contact holes 430a, 430b, and 461 to couple the polysilicon layer 430 and the gate electrode 450 with other elements. As shown in FIG. 4A, the gate electrode 450 may be arranged on the polysilicon layer 430 in such a way that it does not extend past the edges of the polysilicon layer 430. As shown in FIG. 4B, the thin film transistor 400 may include a buffer layer 420, the polysilicon layer 430, a first insulating layer (a gate insulating layer) 440, the gate electrode 450, a second insulating layer (an interlayer insulating layer) 460, and a metal layer 470.

The buffer layer 420 may be deposited on a substrate 410, and the polysilicon layer 430 and the first insulating layer 440 may be arranged on the buffer layer 420. The gate electrode 450 may be arranged on the first insulating layer 440, the second insulating layer 460 may be arranged on the gate electrode 450, and the metal layer 470 may be arranged on the second insulating layer 460.

The buffer layer 420 may include SiNx: SiH₄/NH₄, SiO₂: SiH₄/N₂O, and the like. The buffer layer 420 may be formed using plasma enhanced chemical vapor deposition (PECVD), which is capable of freely adjusting the deposition speed and forming a high quality insulating layer at a relatively low temperature. The buffer layer 420 may include SiO₂ on the upper side and SiNx on the lower side. The buffer layer 420 may prevent foreign matter contained in the substrate 410 from deteriorating the device characteristics by entering the crystallized polysilicon layer 430 during deposition and crystallization of the amorphous silicon layer.

The polysilicon layer 430 may be formed by depositing an amorphous silicon layer (not shown) on the buffer layer 420 and irradiating the amorphous silicon layer with a laser. This process may cause the surface of the polysilicon layer 430 to have steps due to the density difference between the liquid phase and the solid phase in the vicinity of the grain boundary where the amorphous silicon layer is slowly crystallized. As shown in FIG. 5, the steps may include a planar surface and a protruded surface.

To change the amorphous silicon layer into the polysilicon layer, the temperature of the substrate 410 may be maintained at about 400° C. and the amorphous silicon layer may be irradiated by a laser. The gate insulating layer 440 may be deposited on the polysilicon layer 430, and may include SiNx, SiO₂, and the like.

The gate metal layer may be deposited on the gate insulating layer 440, and above the polysilicon layer 430. The gate electrode 450 may be formed by patterning the gate metal layer deposited on the gate insulating layer 440. The surfaces of the gate insulating layer 440 and the gate electrode 450 may also have protruded or stepped surfaces because the gate insulating layer 440 and the gate electrode 450 are sequentially formed above the polysilicon layer 430.

As shown in FIG. 4A, FIG. 4B, and FIG. 5, the width of the gate electrode 450 may be less than the width of the polysilicon layer 430 and may be arranged so that the gate electrode 450 does not extend over the edges of the polysilicon layer 430. The gate insulating layer 440 may be interposed between the gate electrode 450 and the polysilicon layer 430. The gate electrode 450 may be arranged so that it is approximately centered symmetrically in the center portion of the polysilicon layer 430. The distance between the gate electrode 450 and the polysilicon layer 430 and their relative positions may be changed to accommodate equipment used to form the gate electrode 450. The width of the gate electrode 450 may be less than the width of the polysilicon layer 430 by about 0.1 μm and the gate electrode may be arranged in the center portion of the polysilicon layer 430. In other words, (v) in FIG. 4A, FIG. 4B, and FIG. 5 may be about 0.1 μm.

FIG. 5 shows an enlarged sectional view of region V in FIG. 4. The width of the gate electrode 450 may be less than the width of the polysilicon layer 430 so that the gate electrode 450 may be arranged only above the polysilicon layer 430. Thus, the gate electrode 450 has no portion overlapping the ends of the polysilicon layer 430, and the gate insulating layer 440 has an approximately uniform thickness at any position between the polysilicon layer 430 and the gate electrode 450.

In an exemplary embodiment, the gate electrode 450 is formed 0.1 μm from the lateral sides of the polysilicon layer 430 using a NIKON stepper FX-702J.

The second insulating layer 460 may then be formed above the first insulating layer 440 and the gate electrode 450 using PECVD. The contact hole 461 for coupling the metal layer 470 with the gate electrode 450 may be formed in the second insulating layer 460. The metal layer 470 may be deposited on the second insulating layer 460, and the source and drain electrodes (not shown) may be formed by patterning the deposited metal layer 470. Other various layers including a planarization layer, a passivation layer, and the like may be formed after forming the source and drain electrodes.

After forming the source and drain electrodes, heat treatment at about 450° C. under a mixture of nitrogen and hydrogen gas may be performed to improve the contact characteristics of the polysilicon layer 430 and the source drain electrodes. A passivation layer (not shown) may be deposited above the source and drain electrodes. The passivation layer in a pad may be removed to complete the polysilicon thin film transistor.

Although not shown in the above embodiment, after forming the gate electrode 450, a new photoresist layer may be deposited on the gate electrode 450. The coated photoresist layer may be slightly wider than that the gate electrode 450. Ion injection may be performed on the photoresist layer to form n-portions at the ends of the polysilicon layer 430, i.e. an active layer, thereby forming an n-well. After removing the photoresist layer, ion doping may be used to form light LDD portions (not shown) at the right and left sides of the gate electrode 450. A process to form p-portions and p-doping to form an active P-portion layer may be additionally be performed.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A thin film transistor, comprising:
a substrate;
a semiconductor layer arranged on the substrate;
a first insulating layer arranged on the substrate and the semiconductor layer;
a gate electrode arranged on the first insulating layer; and
a second insulating layer arranged on the gate electrode and the first insulating layer,
wherein a width of the gate electrode is less than a width of the semiconductor layer.

2. The thin film transistor of claim 1,
wherein the gate electrode is arranged symmetrically in the center portion of the semiconductor layer.

3. The thin film transistor of claim 2,
wherein the width of the gate electrode is about 0.1 μm less than the width of the semiconductor layer.

4. The thin film transistor of claim 2,
wherein edges of the gate electrode are arranged at least about 0.05 μm from edges of the semiconductor layer.

5. The thin film transistor of claim 2,
wherein the semiconductor layer comprises polycrystalline silicon.

6. The thin film transistor of claim 1, further comprising:
at least one contact hole arranged in the second insulating layer; and
a metal layer arranged on the second insulating layer,
wherein the metal layer is electrically coupled with the gate electrode via the at least one contact hole.

7. The thin film transistor of claim 6, further comprising:
at least one contact hole arranged in the first insulating layer and the second insulating layer,
wherein the metal layer is electrically coupled with the semiconductor layer via the at least one contact hole arranged in the first insulating layer and the second insulating layer.

8. The thin film transistor of claim 1, further comprising:
a buffer layer arranged between the substrate and the first insulating layer and between the substrate and the semiconductor layer.

9. A thin film transistor, comprising:
a semiconductor layer;
a first insulating layer arranged on the semiconductor layer;
a gate electrode arranged on the first insulating layer; and
a second insulating layer arranged on the gate electrode and the first insulating layer,
wherein the gate electrode is arranged entirely within the perimeter of the semiconductor layer.

10. The thin film transistor of claim 9,
wherein the gate electrode is arranged symmetrically in the center portion of the semiconductor layer.

11. The thin film transistor of claim 10,
wherein the gate electrode is in the shape of a rectangle.

12. The thin film transistor of claim 11,
wherein the width of the gate electrode is about 0.1 μm less than the width of the semiconductor layer.

13. The thin film transistor of claim 11,
wherein edges of the gate electrode are arranged at least about 0.05 μm from edges of the semiconductor layer.

14. The thin film transistor of claim 11,
wherein the semiconductor layer comprises polycrystalline silicon.
